(19) United States
(12) Patent Application Publication
(10) Pub. No.: US 2025/0212327 A1
(43) Pub. Date: Jun. 26, 2025

(54) PRINTED CIRCUIT BOARD

(71) Applicant: SAMSUNG ELECTRO-MECHANICS CO., LTD., Suwon-si (KR)

(72) Inventors: Kyeong Yub Jung, Suwon-si (KR); Ki Ran Park, Suwon-si (KR); Yong Duk Lee, Suwon-si (KR); Jin Oh Park, Suwon-si (KR); Tae Yang Kim, Suwon-si (KR)

(73) Assignee: SAMSUNG ELECTRO-MECHANICS CO., LTD., Suwon-si (KR)

(21) Appl. No.: 18/958,608

(22) Filed: Nov. 25, 2024

(30) Foreign Application Priority Data
Dec. 20, 2023 (KR) 10-2023-0187017

(51) Int. Cl. H05K 1/09; H01L 23/00; H01L 25/065; H05K 1/11; H05K 1/18

(52) U.S. Cl. CPC H05K 1/09; H05K 1/111; H05K 1/181; H01L 24/16; H01L 24/17; H01L 25/0655; H01L 2224/16227; H01L 2224/17051; H01L 2924/365; H05K 2201/0323; H05K 2201/0338; H05K 2201/094; H05K 2201/10522; H05K 2201/10734

(57) ABSTRACT

A printed circuit board includes: an insulating portion; a first pad disposed on the bottom of the insulating portion; a first solder resist layer disposed on the bottom of the insulating portion, covering at least a portion of the first pad, and having a first opening in at least a portion of the first pad; a first barrier layer disposed on a portion of the first pad corresponding to the first opening; a first surface treatment layer disposed on the first barrier layer; a second pad disposed on the top of the insulating portion; a second solder resist layer disposed on the top of the insulating portion, covering at least a portion of the second pad; a metal post disposed on the second pad; and a second barrier layer disposed between the second pad and the metal post.

### CROSS-REFERENCE TO RELATED APPLICATION(S)

This application claims benefit of priority to Korean Patent Application No. 10-2023-0187017 filed on Dec. 20, 2023 in the Korean Intellectual Property Office, the disclosure of which is incorporated herein by reference in its entirety.

### TECHNICAL FIELD

The present disclosure relates to a printed circuit board.

A multi-chip package including a memory chip such as a high bandwidth memory (HBM) for exponentially increased data processing and a processor chip such as a central processing unit (CPU), a graphics processing unit (GPU), an application specific integrated circuit (ASIC), or a field programmable gate array (FPGA) has been used in accordance with the recent development of artificial intelligence (AI) technology. In particular, the number of CPU and GPU cores in a server product has been rapidly increased, and it is necessary to respond to a finer chip metal post pitch. In particular, research has been continuously conducted for a method of forming a finer pad of a board for connection between the chip and the board, a method of forming a configuration for smoothly performing the connection between the pad and the chip, and a method of increasing yield while improving reliability of the connection between the chip and the board.

An aspect of the present disclosure is to provide a printed circuit board on which a pad and a metal post having a fine pitch may be mounted as the printed circuit board for mounting an electronic component, a semiconductor chip, or the like.

Another aspect of the present disclosure is to provide a printed circuit board which is prevented from a defect caused by galvanic corrosion occurring in a lower pad and a surface treatment layer when forming an upper metal post.

Another aspect of the present disclosure is to provide a printed circuit board having improved reliability.

### SUMMARY

According to an aspect of the present disclosure, a printed circuit board includes: an insulating portion; a first pad disposed on a bottom of the insulating portion; a first solder resist layer disposed on the bottom of the insulating portion, covering at least a first portion of the first pad, and having a first opening overlapping at least a second portion of the first pad; a first barrier layer disposed on the second portion of the first pad corresponding to the first opening; a first surface treatment layer disposed on the first barrier layer; a second pad disposed on the top of the insulating portion; a second solder resist layer disposed on a top of the insulating portion, covering at least a third portion of the second pad, and having a second opening overlapping at least a fourth portion of the second pad; a metal post disposed on the second pad, and having at least a portion disposed in the second opening; and a second barrier layer disposed between the second pad and the metal post.

According to another aspect of the present disclosure, a printed circuit board includes: an insulating portion; a pad disposed on a top of the insulating portion; a solder resist layer disposed on the top of the insulating portion, covering at least a first portion of the pad, and having an opening overlapping at least a second portion of the pad; a barrier layer in contact with the pad, and extending onto portions of an inner wall of the opening and an upper surface of the solder resist; a seed layer disposed on the barrier layer and extending along the barrier layer; and a metal post disposed on the seed layer, wherein the pad includes a first metal, and the barrier layer includes a material different from the first metal of the pad.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an electronic device according to an exemplary embodiment;

FIG. 3A is a cross-sectional view schematically illustrating a printed circuit board according to an exemplary embodiment;

FIGS. 3B and 3C are a cross-sectional view showing enlarged portions of the top and bottom of the printed circuit board, respectively, according to an exemplary embodiment;

FIG. 3D is a cross-sectional view schematically illustrating a printed circuit board according to another exemplary embodiment; and

FIGS. 4 through 15 are cross-sectional views schematically illustrating a manufacturing method of a printed circuit board according to another exemplary embodiment.

### DETAILED DESCRIPTION

Hereinafter, the present disclosure is described with reference to the accompanying drawings. In the accompanying drawings, shapes, sizes, and the like of components may be exaggerated or reduced for clarity.

### Electronic Device

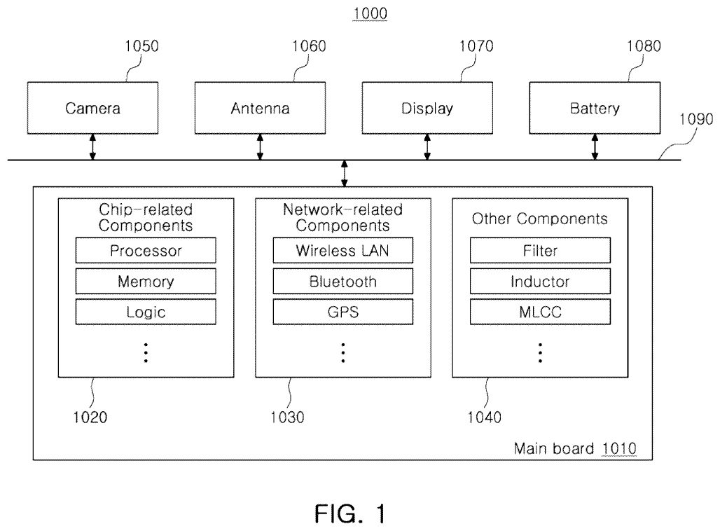

FIG. 1 is a block diagram schematically illustrating an example of an electronic device system.

Referring to the drawing, an electronic device 1000 may accommodate a main board 1010. Chip-related components 1020, network-related components 1030, other components 1040, or the like may be physically and/or electrically connected to the main board 1010. These components may be coupled to other electronic components described below to form various signal lines 1090.

The chip-related components 1020 may include a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, and may also include other type of chip-related components. In addition, the chip-related components 1020 may be combined with each other. The chip-related components 1020 may be a package including the above-mentioned chip or electronic component.

The network-related components 1030 may include a protocol such as wireless fidelity (WiFi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, or 5G protocol, and any other wireless and wired protocols designated after the above-mentioned protocols. However, the network-related components 1030 are not limited thereto, and may also include any of various other wireless or wired standards or protocols. In addition, the network-related components 1030 may be combined with the chip-related components 1020.

Other components 1040 may include a high frequency inductor, a ferrite inductor, a power inductor, ferrite beads, low temperature co-firing ceramics (LTCC), an electro magnetic interference (EMI) filter, a multi-layer ceramic condenser (MLCC), and the like. However, other components 1040 are not limited thereto, and may further include a passive element or the like, in a form of a chip component used for various other purposes in addition to the above-mentioned components. In addition, other components 1040 may be combined with the chip-related components 1020 and/or the network-related components 1030.

The electronic device 1000 may include another electronic component that may be or may not be physically and/or electrically connected to the main board 1010, based on a type of the electronic device 1000. An example of another electronic component may include a camera module 1050, an antenna module 1060, a display 1070, a battery 1080, or the like. However, another electronic component is not limited thereto, and may be an audio codec, a video codec, a power amplifier, a compass, an accelerometer, a gyroscope, a speaker, a mass storage device (e.g., hard disk drive), a compact disk (CD), a digital versatile disk (DVD), or the like. In addition, another electronic component may include another electronic component used for various purposes, based on the type of the electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive, or the like. However, the electronic device 1000 is not limited thereto, and may also be any other electronic device that processes data.

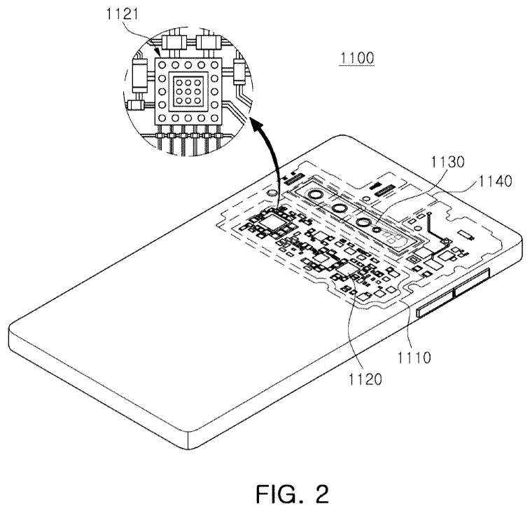

FIG. 2 is a perspective view schematically illustrating an electronic device according to an exemplary embodiment.

Referring to the drawing, the electronic device may be, for example, a smartphone 1100. The smartphone 1100 may accommodate a motherboard 1110, and various components 1120 may be physically and/or electrically connected to the motherboard 1110. In addition, the motherboard 1110 may accommodate another component that may be or may not be physically and/or electrically connected thereto, such as a camera module 1130 and/or a speaker 1140. Some of the components 1120 may be the chip-related components, for example, a component package 1121, and are not limited thereto. The component package 1121 may have the form of a printed circuit board on which the electronic component including an active component or a passive component is surface mounted. Alternatively, the component package 1121 may have the form of a printed circuit board in which the active component or the passive component is embedded. Meanwhile, the electronic device is not necessarily limited to the smartphone 1100, and may be another electronic device as described above.

### Printed Circuit Board

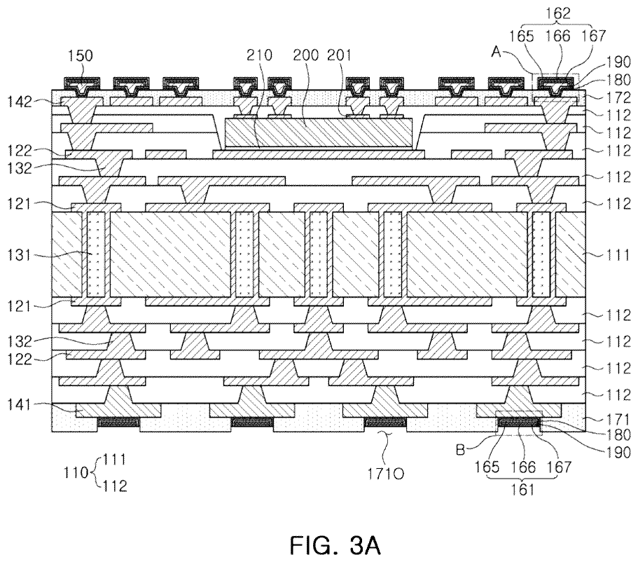

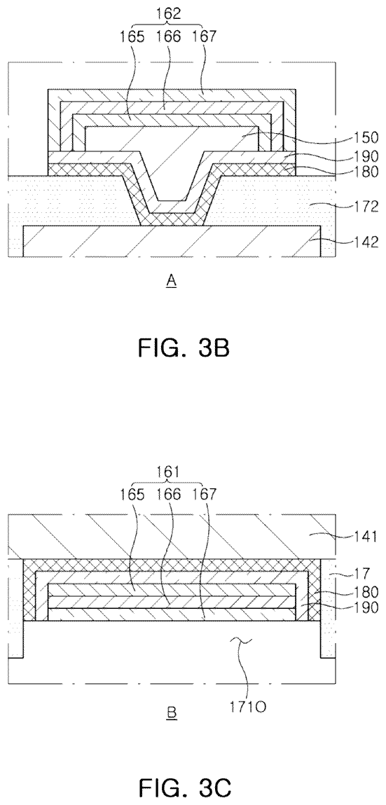

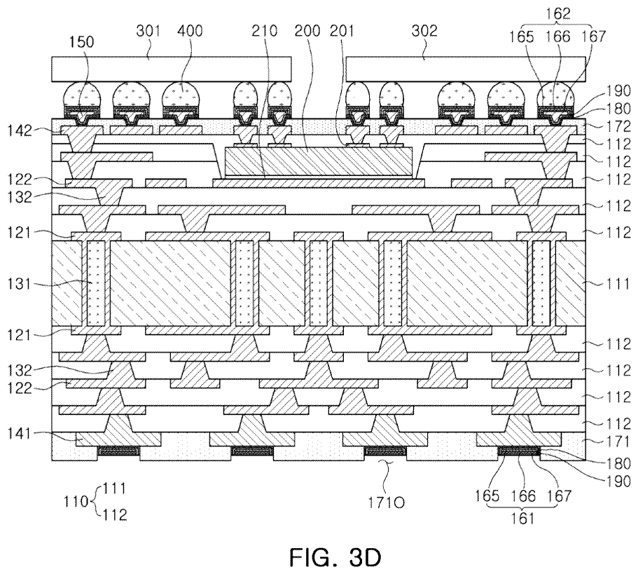

FIG. 3A is a cross-sectional view schematically illustrating a printed circuit board according to an exemplary embodiment.

FIGS. 3B and 3C are a cross-sectional view showing enlarged portions of the top and bottom of the printed circuit board, respectively, according to an exemplary embodiment. In detail, FIGS. 3B and 3C show an enlarged view of each of regions A and B of the printed circuit board, respectively, according to an exemplary embodiment. A specific arrangement relationship in the regions A and B in FIG. 3A may be understood by referring to FIGS. 3B and 3C, respectively.

Referring to FIG. 3A, the printed circuit board according to an exemplary embodiment may include: an insulating portion 110; a first pad 141 disposed on the bottom of the insulating portion 110; a first solder resist layer 171 disposed on the bottom of the insulating portion 110, covering at least a portion of the first pad 141, and having a first opening 171O in at least a portion of the first pad 141; a barrier layer 180 disposed on a portion of the first pad 141 corresponding to the first opening 171O; a first surface treatment layer 161 disposed on the barrier layer 180; a second pad 142 disposed on the top of the insulating portion 110; a second solder resist layer 172 disposed on the top of the insulating portion 110, covering at least a portion of the second pad 142, and having a second opening 172O in at least a portion of the second pad 142; and a metal post 150 disposed on the second pad 142, and having at least a portion disposed in the second opening 172O.

In addition, in the printed circuit board according to an exemplary embodiment, the barrier layer 180 may be in contact with the second pad 142 and extend to portions of an inner wall of the second opening 172O and an upper surface of the second solder resist layer 172. The printed circuit board may include a seed layer 190 disposed on the barrier layer 180 and extending along the barrier layer 180. The metal post 150 may be disposed on the seed layer 190, and the barrier layer 180 may include a metal different from a metal in the seed layer 190.

The printed circuit board according to an exemplary embodiment may include the barrier layer 180 between the first pad 141 and the first surface treatment layer 161. Therefore, the first pad 141 may not be in direct contact with the first surface treatment layer 161, and the first pad 141 may be covered by the barrier layer 180. The first pad 141 may be covered by the barrier layer 180, thus preventing galvanic corrosion from occurring due to etching in a process of forming the metal post 150 on the second pad 142.

In addition, the printed circuit board according to an exemplary embodiment may include the barrier layer 180 between the second pad 142 and the metal post 150, and the second pad 142 may thus be covered by the barrier layer 180. The second pad 142 may be covered by the barrier layer 180 before forming the metal post 150 on the second pad 142, and may thus be prevented from the galvanic corrosion caused by the etching in the process of forming the metal post 150 on the second pad 142.

The galvanic corrosion may occur when two metals having different electrochemical properties, such as standard reduction potential, are exposed to a corrosive solution while being electrically connected to each other, and refers to a phenomenon in which the corrosion occurs in a metal that is more active or has a lower standard reduction potential value among the two metals. A third metal layer 167 disposed on the outermost side of the first surface treatment layer 161 may include gold (Au) on the outermost side, and the second pad 142 and the metal post 150 may respectively include copper (Cu). The second pad 142 and the first surface treatment layer 161 may be simultaneously exposed to a solution, i.e., an etchant for soft etching or the like in a process of preprocessing the second pad 142 through the second opening 172O of the second solder resist layer 172 to form the metal post 150 on the second pad 142, a process of removing the seed layer to form the metal post 150, or the like. Accordingly, the second pad 142, which includes copper (Cu) having a relatively low standard reduction potential, may act as a negative electrode, and the third metal layer 167 of the first surface treatment layer 161, which includes gold (Au) having a relatively high standard reduction potential, may act as a positive electrode, thus causing the galvanic corrosion between the second pad 142 and the first surface treatment layer 161. Therefore, the galvanic corrosion may occur on the second pad 142, thus causing a defect in the second pad 142, and the defect may also occur in the metal post 150 disposed on the second pad 142. Meanwhile, the metal materials in the third metal layer 167 of the first surface treatment layer 161 and the second pad 142 are not necessarily limited to these metals, and may include in all cases where the metal materials have the standard reduction potential different from each other, and the galvanic corrosion may occur between the second pad 142 and the third metal layer 167 disposed on the outermost side of the first surface treatment layer 161.

As described above, in the printed circuit board according to an exemplary embodiment, the barrier layer 180 may be formed on the first pad 141 or the second pad 142, the seed layer 190 may then be formed, and each of the first pad 141 and the second pad 142 may then be covered by the barrier layer 180. Therefore, it is possible to prevent the second pad 142 and the first surface treatment layer 161 from being exposed to the etchant simultaneously in a process of forming the seed layer 190. Therefore, it is also possible to prevent the galvanic corrosion from occurring in the process of implementing the metal post 150 on the second pad 142. In more detail, the barrier layer 180 may be disposed conformally on a lower surface of the first pad 141, i.e., at least a portion of an inner wall of the first opening 171O formed in the first solder resist layer 171, thus preventing the galvanic corrosion from occurring in the second pad 142. Meanwhile, a portion of the lower barrier layer 180 may be removed in a final process of a subsequent manufacturing method. Therefore, the barrier layer 180 may be disposed on the lower surface of the first pad 141, and disposed on at least a portion of the inner wall of the first opening 171O.

In addition, the printed circuit board according to an exemplary embodiment may also have the barrier layer disposed on the second pad 142. Therefore, it is also possible to prevent the galvanic corrosion from occurring in the second pad 142 in the process of removing a portion of the seed layer 190 included in the processes of forming the metal post 150.

The barrier layer 180 may include a material having electrical conductivity, and may use a material different from the metal material included in the first pad 141 or the second pad 142.

The printed circuit board according to an exemplary embodiment may prevent the galvanic corrosion from occurring in the second pad 142, and accordingly, the defect may not occur even when the second pad 142 or the metal post 150 are designed to have a fine pitch. Therefore, it may be advantageous to connect components each having the fine pitch to each other, such as semiconductor chips disposed on the top of the printed circuit board.

The insulating portion 110 may include one or more insulating layers, include the first insulating layer 111, which is a core layer, and a second insulating layer 112, which is a build-up insulating layer, is not necessarily limited thereto, and may omit the first insulating layer 111, which is the core layer. The insulating portion 110 may include an insulating material. The insulating material may include a thermosetting resin such as an epoxy resin, a thermoplastic resin as polyimide, or a material including an inorganic filler, an organic filler, and/or a glass fiber (i.e., glass fiber, glass cloth or glass fabric) together with this resin. The insulating material may be a photosensitive material and/or a non-photosensitive material. For example, the insulating material of the insulating portion 110 may be an insulating material of Ajinomoto build-up film (ABF), is not limited thereto, and may include prepreg (PPG), resin coated copper (RCC), photo imageable dielectric (PID), FR-4, bismaleimide triazine (BT), or the like. However, the insulating material is not limited thereto, and may use another material having excellent rigidity, such as a glass material, if necessary. As a non-limiting example, the first insulating layer 111, which is the core layer, may include a glass board. As such, the materials of the first insulating layer 111 and the second insulating layer 112, included in the insulating portion 110, may not be limited. The first insulating layer 111 and the second insulating layer 112 may include the same insulating material, and may also include different insulating materials.

A first wiring layer 121 and a second wiring layer 122 may respectively include one or more wiring layers, and include the first wiring layer 121 disposed on the first insulating layer 111, and the second wiring layer 122 as a build-up wiring layer disposed on or in the second insulating layer 112.

The first wiring layer 121 and the second wiring layer 122 may respectively include the metal material. The metal material may use copper (Cu), aluminum (Al), silver (Ag), tin (Sn), gold (Au), lead (Pb), titanium (Ti), or an alloy thereof. The metal material may include copper (Cu), and is not limited thereto. The first wiring layer 121 and the second wiring layer 122 may include different metal materials. Each wiring layer may perform various functions based on its design. For example, the wiring layer may include a signal pattern, a power pattern, a ground pattern, or the like, is not limited thereto, and may function as a pad on which the electronic component or the chip, or the like is mounted or as a stopper to form a cavity. Each pattern may have any of various forms such as a line, a plane, and the pad. Each wiring layer may have a different pitch based on its function. For example, a pitch between the second wiring layers 122 and a pitch between the patterns may be narrowed in a case where at least a portion of the second wiring layer 122 requires a high-density fine pitch for its connection to a connection structure, the semiconductor chip, or the like. The pitch between the patterns in the wiring layer may be wider in another case, such as performing a signal connection, other than the above case.

The first wiring layer 121 or the second wiring layer 122 may be formed using any of a semi additive process (SAP), a modified semi additive process (MSAP), a tenting (TT) method, and a subtractive method, and is not limited thereto. Each of the first wiring layer 121 and the second wiring layer 122 may include an electroless plating layer (or chemical copper) as its seed layer and an electrolytic plating layer (or electric copper) as a plating layer, and is not limited thereto. The wiring layer may also include a sputtering layer instead of the chemical copper as the electroless plating layer. The wiring layer may further include a copper foil if necessary.

The printed circuit board according to an exemplary embodiment may include a first via layer 131 connecting the first wiring layers 121 to each other and a second via layer 132 connecting the second wiring layers 122 to each other. The second via layer 132 may include one or more via layers. The first via layer 131 may be a through via passing through the first insulating layer 111, and the second wiring layer 122 may be a build-up via layer passing through at least a portion of the second insulating layer 112. Here, the second via layer 132 may connect the second wiring layer 122 and the first pad 141 to each other, or connect the second wiring layer 122 and the second pad 142 to each other.

The first via layer 131 may include a metal layer formed on a wall of the through hole passing through the first insulating layer 111 and a plug that fills the metal layer. The metal layer may include copper (Cu), aluminum (Al), silver (Ag), tin (Sn), gold (Au), nickel (Ni), lead (Pb), titanium (Ti), or an alloy thereof, include copper (Cu), and is not limited thereto. The plug may include ink of the insulating material. The metal layer may include the electroless plating layer (or chemical copper) or the electrolytic plating layer (or electric copper), and is not limited thereto. The metal layer may include the sputtering layer instead of the electroless plating layer, and include both the layers. The first via layer 131 may perform various functions based on its design. For example, the first via layer 131 may include a ground via, a power via, a signal via, or the like.

The second via layer 132 may include a micro via. The micro via may be a filed via that fills a via hole or a conformal via disposed along a wall of the via hole. The micro vias may be disposed as a stacked type and/or a staggered type. Each second via layers 132 may include a metal, and the metal may include copper (Cu), aluminum (Al), silver (Ag), tin (Sn), gold (Au), nickel (Ni), lead (Pb), titanium (Ti), or an alloy thereof. The metal material may include copper (Cu), and is not limited thereto. Each second via layer 132 may include the electroless plating layer (or chemical copper) and the electrolytic plating layer (or electric copper), and is not limited thereto. The second via layer may include the sputtering layer instead of the electroless plating layer, and include both the layers. The second via layer 132 may perform various functions based on a design of the corresponding layer. For example, the second via layer 132 may include the ground via, the power via, the signal via, or the like.

The printed circuit board according to an exemplary embodiment may include the first pad 141 disposed on the bottom of the insulating portion 110. The first pad 141 may be disposed on or in the lowermost second insulating layer 112. FIG. 3A shows that the first pad 141 is disposed on the second insulating layer 112 and protrudes from the bottom of the second insulating layer 112, is not necessarily limited thereto, and have a so-called coreless structure in which the first pad 141 is buried in the bottom of the second insulating layer 112. The first pad 141 may be connected to at least a portion of the second wiring layer 122 through one of the second via layers 132.

The first pad 141 may include the metal material, and the metal material may include copper (Cu), aluminum (Al), silver (Ag), tin (Sn), gold (Au), nickel (Ni), lead (Pb), titanium (Ti), and/or an alloy thereof. The metal material may include copper (Cu), and is not limited thereto. The first pad 141 may be disposed on the lowermost side of the printed circuit board, and function as a connection pad for a lower surface of the printed circuit board to be connected to another component such as the main board. However, the first pad 141 is not limited thereto, and may function as a member for connection to a component having the fine pitch, such as the semiconductor chip. The pitch may be designed in various ways based on a function. The first pad 141 may perform various functions based on its design. For example, the first pad 141 may include a ground pad, a power pad, a signal pad, or the like. Here, the signal pad may include a pad for electrical connection between various signals other than ground signals, power signals, or the like, for example, data signals.

The printed circuit board according to an exemplary embodiment may include the second pad 142 on the top of the insulating portion 110. The second pad 142 may be disposed on or in the uppermost second insulating layer 112. FIG. 3A shows the first pad 141 is disposed on the second insulating layer 112 while protruding upward from the second insulating layer 112, and is not necessarily limited thereto. The second pad 142 may also have a coreless structure buried in the second insulating layer 112. Here, the second pad 142 may have a finer pitch pad structure than the first pad 141. Therefore, as a non-limiting example, a structure of buring the second pad 142 in the second insulating layer 112 may be preferable to a structure of buring the first pad 141 in the second insulating layer 112. The second pad 142 may be connected to at least a portion of the second wiring layer 122 through one via layer 132 among the second via layers 132.

The second pad 142 may include the metal material, and the metal may include copper (Cu), aluminum (Al), silver (Ag), tin (Sn), gold (Au), nickel (Ni), lead (Pb), titanium (Ti), and/or an alloy thereof. The metal material may include copper (Cu), and is not limited thereto. The second pad 142 may be disposed on the uppermost side of the printed circuit board, may be a region in which the electronic component, the chip, or the like is mounted, and may be connected to a circuit pattern to perform the signal connection with another pad. The second pad 142 may perform various functions based on its design. For example, the second pad 142 may include the ground pad, the power pad, the signal pad, or the like. Here, the signal pad may include the pad for the electrical connection between the various signals other than the ground signals, the power signals, or the like, for example, the data signals. The pitch between the second pads 142 may be narrower in a case where the second pad 142 requires the high-density fine pitch enabling the semiconductor chip or the like to be mounted on the pad, whereas the pitch between the second pads 142 may be wider in a case where the second pad 142 is used to mount the electronic component. In addition, the second pad 142 may have a narrower pitch in a region in which the semiconductor chip or the like is mounted using another configuration such as a connection structure 200.

The first pad 141 or the second pad 142 may be formed using any of the semi additive process (SAP), the modified semi additive process (MSAP), the tenting (TT) method, and the subtractive method, is not limited thereto, and may be formed using any method available to those skilled in the art.

The printed circuit board according to an exemplary embodiment may include the first solder resist layer 171 and the second solder resist layer 172 respectively disposed on the bottom and the top of the insulating portion 100. The first solder resist layer 171 may be disposed on the lowermost second insulating layer 112, and the second solder resist layer 172 may be disposed on the uppermost second insulating layer 112.

Each of the first solder resist layer 171 and the second solder resist layer 172 may be disposed on the outermost side of the printed circuit board to protect the printed circuit board from the outside. The first solder resist layer 171 or the second solder resist layer 172 may use a known solder resist. Each of the first solder resist layer 171 and the second solder resist layer 172 may include the thermosetting resin and the inorganic filler dispersed in the thermosetting resin. However, the solder resist layer may include no glass fiber. Such an insulating resin may be a photosensitive insulating resin, the filler may be the inorganic filler and/or the organic filler, and is not limited thereto. The solder resist layer may use another polymer material if necessary. It may be advantageous to form a fine opening when the solder resist layer uses the photosensitive insulating resin, the solder resist layer is not limited thereto, and the solder resist layer may include a non-photosensitive insulating resin to also form the fine opening by using a ultraviolet (UV) laser.

The first solder resist layer 171 may have the first opening 171O, and at least a portion of the first pad 141 may be exposed through the first opening 171O. The fact that a portion of the first pad 141 may be exposed through the first opening 171O may indicate that the first solder resist layer 171 does not cover the first pad 141 in a region in which the first opening 171O is formed. That is, the fact that a portion of the first pad 141 may be exposed through the first opening 171O may indicate a case where not only the first pad 141 is exposed outward from the printed circuit board, but also the first solder resist layer 171 does not cover a portion of the first pad 141, and a portion of the first pad 141 may thus be connected to another configuration.

Meanwhile, FIG. 3A shows that the first opening 171O of the first solder resist layer 171 exposes a portion of an upper surface of the first pad 141. However, the first solder resist layer 171, the first opening 171O, and the first pad are not limited to being arranged in a solder mask defined (SMD) form, and may be arranged in a non-solder mask defined (NSMD) form, or the like. As such, a relationship between the first pad 141 and the first solder resist layer 171 is not limited to what is shown in the drawing. When the components described above are aligned in the NSMD form, a width of the first opening 171O in the first solder resist layer 171 may be wider than a width of the first pad 141, the upper surface of the first pad 141 may be exposed through the first solder resist layer 171, and a side surface of the first pad 141 may be exposed through the first solder resist layer 171.

The second solder resist layer 172 may cover at least a portion of the second pad 142. In addition, the metal post 150 may pass through a portion of the second solder resist layer 172, and may protrude from the second solder resist layer 172. The fact that the metal post 150 protrudes beyond the second solder resist layer 172 may indicate that an upper surface of the metal post 150 may be higher than an upper surface of the solder resist layer 172.

The second solder resist layer 172 may also expose at least a portion of the second pad 142 through the second opening, and the second opening may be filled by the metal post 150. Here, a lower width of the metal post 150 may be smaller than a width of the second pad 142 in a region in which the metal post 150 and the second pad 142 are in contact with each other. Meanwhile, as described above, a width of the second opening formed in the second solder resist layer 172 may also have various widths, such as the width of the first opening 171O, and the width of the metal post 150 may thus be greater than the width of the second pad 142.

The printed circuit board according to an exemplary embodiment may include the barrier layer 180 disposed on at least a portion of the first pad 141. The barrier layer 180 may be disposed on at least a portion of the first pad 141, and may extend to a portion of the first solder resist layer 171, such as extending onto the inner wall of the first opening 171O. That is, the barrier layer 180 may cover at least a portion of the first pad 141 to thus prevent the first pad 141 from being externally exposed.

Meanwhile, the barrier layer 180 may also be disposed on at least a portion of the second pad 142, and extend to the inner wall of the second opening 172O to thus extend to at least a portion of the upper surface of the second solder resist layer 172. That is, the barrier layer 180 may cover at least a portion of the second pad 142 to thus prevent the second pad 142 from being externally exposed.

The barrier layer 180 may include the material having electrical conductivity. The barrier layer 180 may include the metal material, is not limited thereto. It is sufficient for the barrier layer 180 to use, as the material having electrical conductivity, any material which is disposed between the metal post 150 and the second pad 142 and may conduct the electricity. The barrier layer 180 may use a material disposed between the first pad 141 and the first surface treatment layer 161 and conducting electricity to be connected to the outside without limitation. That is, the material of the barrier layer is not limited, and the barrier layer may use any material as long as the corresponding material does not include the metal material that is substantially the same as the first pad 141 or the second pad 142 for copper (Cu) used as its metal material to function to prevent the pad and the first surface treatment layer 161 or a second surface treatment layer 162 to be simultaneously exposed to an aqueous solution environment. The barrier layer 180 may include the metal having a lower standard reduction potential value than the metal included in the first pad 141 and the second pad 142. As a non-limiting example, the barrier layer 180 may include the metal having a lower standard reduction potential value than copper (Cu), such as titanium (Ti), nickel (Ni), aluminum (Al), tin (Sn), lead (Pb), or an alloy thereof. Meanwhile, the barrier layer 180 is not limited thereto, the barrier layer 180 may not use the metal material, and may include a conductive inorganic carbon-based material or a conductive organic carbon-based material, or the like. As such, it is sufficient for the barrier layer 180 to include the material that is substantially different from that of the first pad 141 or the second pad 142.

The barrier layer 180 may be a coating layer formed using the thin film deposition method, such as an atomic layer deposition (ALD) method or a molecular vapor deposition (MVD) method. Here, the barrier layer may have a thin film shape formed by the deposition method. Meanwhile, the barrier layer is not necessarily limited thereto, and may be formed by deposition through sputtering. Meanwhile, a method of forming the barrier layer 180 may depend on the material of the barrier layer 180, and is not necessarily limited to the deposition method. The barrier layer 180 may be thinner than the first pad 141 or the second pad 142, and may be thinner than the first surface treatment layer 161.

The printed circuit board according to an exemplary embodiment may further include the seed layer 190 disposed on the barrier layer 180. The seed layer 190 may function as a plating seed to form the metal post 150. The seed layer 190 may be disposed on the barrier layer 180 and extend along the barrier layer, and the seed layer 190 and the barrier layer 180 may be disposed on the bottom of the metal post 150 and the second surface treatment layer 162 because unnecessary portions are removed after forming the metal post 150 and the second surface treatment layer 162 in a manufacturing process of the printed circuit board. The seed layer 190 may be disposed on the barrier layer 180 disposed on the bottom of the printed circuit board. The seed layer 190 may also be formed on the bottom of the printed circuit board. Accordingly, unlike a case where the seed layer 190 is formed only on the top of the printed circuit board, it is possible to adjust a potential difference between the top and the bottom of the printed circuit board. However, the seed layer 190 is not limited to only what is shown in FIGS. 3A to 3C, the present disclosure may omit the seed layer 190 disposed on the bottom of the printed circuit board, and the seed layer 190 may be disposed only on the top of the printed circuit board where the metal post 150 is disposed.

The seed layer 190 may include the metal material, and the metal material may use copper (Cu), aluminum (Al), silver (Ag), tin (Sn), gold (Au), lead (Pb), titanium (Ti), or an alloy thereof. The metal material may include copper (Cu), and is not limited thereto. The seed layer 190 may include the electroless plating layer (or chemical copper) formed through electroless plating, is not limited thereto, may include the sputtering layer formed through the sputtering instead of the electroless plating, and may also include both the plating layer and the sputtering layer. The seed layer 190 is not limited thereto, and may use any metal that may function as a seed for electroplating, such as including the copper foil, without limitation, if necessary.

The printed circuit board according to an exemplary embodiment may further include the first surface treatment layer 161 disposed on at least a portion of the first pad 141. The surface treatment layer may be disposed on the first pad 141 and in the first opening 171O of the first solder resist layer 171. The first surface treatment layer 161 may be disposed on the first pad 141, disposed on the barrier layer 180, and disposed on the seed layer 190. Meanwhile, as described above, the seed layer 190 may not be disposed on the bottom of the printed circuit board. Therefore, in this case, the first surface treatment layer 161 may be disposed on the barrier layer 180. The first surface treatment layer 161 may improve adhesion and signal transmission between the first pad 141 and a connecting member.

The first surface treatment layer 161 may include a first metal layer 165, a second metal layer 166, and the third metal layer 167, and the first metal layer 165, the second metal layer 166, and the third metal layer 167 may be disposed sequentially. Meanwhile, the metal layers are not necessarily limited thereto, and boundaries of the respective metal layers may not be clearly distinguished from each other.

The first metal layer 165 may include nickel (Ni), the second metal layer 166 may include palladium (Pd), and the third metal layer 167 may include gold (Au). That is, the first surface treatment layer 161 may be at least a portion of an electroless nickel electroless palladium immersion gold (ENEPIG) structure. Meanwhile, the first surface treatment layer 161 is not limited thereto, and may omit the second metal layer 166. In this case, the first surface treatment layer 161 may be at least a portion of an electroless nickel immersion gold (ENIG) structure. Alternatively, the first surface treatment layer 161 may also omit the first metal layer 165, and include only gold (Au) plating on the outermost side. The first surface treatment layer 161 may include the third metal layer 167 on the outermost side, and the third metal layer 167 including gold (Au) may be disposed on the outermost side of the printed circuit board. The third metal layer 167 may include the plating layer, and may be formed by performing the electroless plating or substitution plating. The third metal layer 167, which is the outermost side of the first surface treatment layer 161, may include the gold (Au) plating layer, and the galvanic corrosion may thus occur in the second pad 142, which may include copper (Cu).

The barrier layer 180 may be formed on the first pad 141, the seed layer 190 may then be formed, and the first surface treatment layer 161 may then be formed. Accordingly, the first surface treatment layer 161 may be in contact with the barrier layer 180 and the seed layer 190, which are conformally disposed in the first opening 171O of the first solder resist layer 171. In more detail, the barrier layer 180 and the seed layer 190 may each extend from the first pad 141 to at least a portion of the inner wall of the first opening 171O, and the first surface treatment layer 161 may have a height at which the barrier layer 180 or the seed layer 190 extends. This configuration may be a result of forming the first surface treatment layer 161 after forming the barrier layer 180 and the seed layer 190 in the manufacturing method of a printed circuit board, and then removing a portion of the seed layer 190 and a portion of the barrier layer 180. Meanwhile, an arrangement relationship of the barrier layer 180, the seed layer 190, and the first surface treatment layer 161 is not necessarily limited to what is shown in FIGS. 3A to 3C. The specific height or arrangement level may be changed without limitation as long as the barrier layer 180, the seed layer 190, and the first surface treatment layer 161 are sequentially stacked on the first pad 141.

The printed circuit board according to an exemplary embodiment may further include the metal post 150 disposed on at least a portion of the second pad 142. The metal post 150 may be disposed on the second pad 142 and may pass through at least a portion of the second solder resist layer 172. The metal post 150 may include the metal material. The metal material may use copper (Cu), aluminum (Al), silver (Ag), tin (Sn), gold (Au), lead (Pb), titanium (Ti), or an alloy thereof. The metal material may include copper (Cu), and is not limited thereto. The metal post 150 may be formed using any of the semi additive process (SAP), the modified semi additive process (MSAP), the Tenting (TT) method, or the subtractive method, is not limited thereto, and may be formed using any method available to those skilled in the art. The metal post 150 may be formed by performing the electroplating using the seed layer 190 as the plating seed, and the metal post 150 may include the electrolytic plating layer (or electric copper).

The metal post 150 may be a region in which the electronic component, the chip, or the like is mounted, and may protrude to facilitate smooth connection when the electronic component, the chip, or the like are mounted on the second pad 142. The metal post 150 may perform various functions based on the design of the second pad 142. The metal post 150 may transmit and receive an electrical signal with the second pad 142.

Not only the pitch between the second pads 142 but also the pitch between the metal posts 150 may be narrowed when the second pad 142 requires the high-density fine pitch enabling the semiconductor chip or the like to be mounted thereon. The metal post 150 may be disposed on the second pad 142, which may reduce a possibility that a short circuit occurs in a connecting member 170 disposed between the semiconductor chip and the metal post 150, and a defect that the semiconductor chip is separated from the printed circuit board even when the semiconductor chip of the fine pitch is mounted on the pad. In addition, the metal post 150 may be disposed on the second pad 142, which structure may secure the adhesion through the metal post 150 rather than a structure in which the connecting member, such as solder, is disposed directly on the second pad 142, thereby improving reliability of the printed circuit board.

The printed circuit board according to an exemplary embodiment may further include the second surface treatment layer 162 disposed on at least a portion of the metal post 150. The second surface treatment layer 162 may also have the first metal layer 165, the second metal layer 166, and the third metal layer 167, which are disposed sequentially. However, the metal layer may be omitted or added as described above regarding the first surface treatment layer 161. As described above, the boundaries of the respective metal layers may not be clearly distinguished from each other. Descriptions of the first metal layer 165, the second metal layer 166, and the third metal layer 167 may be applied to the descriptions of those in the first surface treatment layer 161, and the description thus omits redundant descriptions thereof.

The metal post 150 may protrude from the second solder resist layer 172. Therefore, the second surface treatment layer 162 may be formed along the exposed surface of the metal post 150. That is, the second surface treatment layer 162 may cover each of the upper surface and side surface of the metal post 150. The second surface treatment layer 162 may cover the side surface of the metal post 150, and the side surface of the metal post 150 may not be externally exposed. The side surface of the metal post 150 may not be externally exposed. It is thus possible to prevent the galvanic corrosion from occurring between the first surface treatment layer 161 and/or the second surface treatment layer 162 and the metal post 150 during the process of removing a portion of the seed layer 190 in the manufacturing method of a printed circuit board. It is also possible to prevent the galvanic corrosion from occurring between the first surface treatment layer 161 and/or the second surface treatment layer 162 and the second pad 142.

Meanwhile, the metal post 150 of the printed circuit board according to an exemplary embodiment may have a surface roughness of its upper surface and a surface roughness of its side surface which are substantially the same as each other in a region in which the metal post 150 is in contact with the second surface treatment layer 162. The surface roughness may be the result of using a second resist during a process of forming the second surface treatment layer 162 in the manufacturing method of a printed circuit board according to another exemplary embodiment. The side surface of the metal post 150 may be damaged during a process of performing additional processing on the resist when forming the second surface treatment layer 162 by performing the additional processing on the resist used in the process of forming the metal post 150 for the resist to have an opening wider than the width of the metal post 150. In this case, ununiformity may occur on the side surface of the metal post 150, and the side surface of the metal post 150 may have the roughness greater than the surface roughness of its upper surface. On the other hand, in the printed circuit board according to an exemplary embodiment, a first resist for forming the metal post 150 may be removed, and the second surface treatment layer 162 for forming the second surface treatment layer 162 may be formed separately. Therefore, the side surface of the metal post 150 may not be damaged, and the side surface of the metal post 150 may have substantially the same roughness as its upper surface. The surface roughness may be measured by capturing a cross section of the printed circuit board that is cut in a stacking direction by using a scanning microscope or the like, and the surface roughness may be measured using a known method for calculating the roughness. For example, the surface roughness may be measured using arithmetic average roughness (Ra) or ten-point average roughness (Rz). However, roughness measurement of the upper surface of the metal post 150 and roughness measurement of a side surface thereof may be performed using the same references and methods. The fact that the roughnesses of the side and upper surfaces of the metal post 150 are substantially the same as each other may be a result of a difference in the manufacturing method described above, is not limited thereto, and a surface of the second surface treatment layer 162 that is in contact with the metal post 150 may have substantially uniform surface roughness. Meanwhile, the second surface treatment layer 162 may be formed using the separate second resist rather than processing an additional opening in the resist, and an opening region in the second resist may thus also have a flat surface rather than an non-uniform surface roughness. Accordingly, the third metal layer 167 of the second surface treatment layer 162 may also have a surface roughness of its side surface and a surface roughness of its upper surface which are substantially the same or almost similar to each other. Meanwhile, as the resist is not processed, the seed layer 190 disposed in a region in which the second surface treatment layer 162 is formed may not be damaged. Therefore, the seed layer 190 in the region in which the seed layer 190 is in contact with the metal post 150 and the seed layer 190 in the region in which the seed layer 190 is in contact with the second surface treatment layer 162 may have substantially the same surface roughness. Meanwhile, the printed circuit board is not limited thereto, and the description of the printed circuit board according to an exemplary embodiment may use any content which may be confirmed when the metal post 150 is formed, the first resist is then removed, and the second surface treatment layer 162 is then formed using the second resist without limitation.

The printed circuit board according to an exemplary embodiment may further include the connection structure 200 and an adhesive layer 210. The connection structure 200 may be connected to the electronic component such as the semiconductor chip. For example, the connection structure 200 may have a bridge structure. The connection structure 200 may include a body having a pattern implemented on the insulating material, and a connection part 201 to be connected to the wiring layer. The connection structure 200 may be an organic board, a silicon bridge having a circuit implemented on a silicon wafer, or the like. The connection structure 200 is not limited thereto, and may be one semiconductor chip buried in the insulating portion 110 of the printed circuit board.

The connection structure 200 may be disposed in a cavity passing through at least a portion of the second insulating layer 112 and buried in the second insulating layer 112. The connection structure 200 may further include the adhesive layer 210 in order for the connection structure 200 to be mounted in the cavity. The structure and mounting of the connection structure 200 may be implemented using any structure and method available to those skilled in the art.

FIGS. 3A to 3C show that the first metal layer 165, the second metal layer 166, the third metal layer 167, the seed layer 190 and the barrier layer 180 have similar thicknesses, which is only an element provided to assist in understanding of their arrangement relationship, and is not necessarily limited thereto.

Meanwhile, the printed circuit board according to an exemplary embodiment is not limited to the configurations shown in FIGS. 3A to 3C, may further include another configuration, and may omit some configurations in some cases. That is, the printed circuit board according to an exemplary embodiment may further include or omit a configuration available to those skilled in the art.

FIG. 3D is a cross-sectional view schematically illustrating a printed circuit board according to another exemplary embodiment.

Referring to FIG. 3D, a printed circuit board according to another exemplary embodiment may further include semiconductor chips 301 and 302 disposed on the metal posts 150, and further include a connecting member 400 connecting the metal post 150 and the semiconductor chip 301 or 302 to each other.

The semiconductor chip 301 or 302 may be an integrated circuit (IC) in which hundreds to millions of chips are integrated into one chip. Each of the semiconductor chips 301 and 302 may be a processor chip such as a central processor (e.g., CPU), a graphics processor (e. g., GPU), a field programmable gate array (FPGA), a digital signal processor, an encryption processor, a microprocessor, or microcontroller, specifically, an application processor (AP), is not limited thereto, may be a logic chip such as an analog-to-digital converter, an application-specific IC (ASIC), or a memory controller (MC) chip, may be a memory chip such as a dynamic random access memory (DRAM) chip, a static random access memory (SRAM) chip, a flash memory chip, a phase-change random access memory (PRAM) chip, a magnetic random access memory (MRAM) chip, a resistive random access memory (RRAM) chip, an electrically erasable and programmable read-only memory (EEPROM) chip, or a high bandwidth memory (HBM) chip, or a combination of these chips.

The semiconductor chip 301 or 302 may include a body and a connection pad. A surface of the semiconductor chip where the connection pad for its connection to the metal post 150 is disposed may be an active surface, and the opposite surface may be an inactive surface. The semiconductor chip is not limited thereto, may have double-sided connection, or may have a three-dimensional structure in some The semiconductor chip 301 or 302 may be formed based on an active wafer. In this case, the chip may use silicon (Si), germanium (Ge), gallium arsenide (GaAs), or the like as a base material included in the body. Various circuits may be formed in the semiconductor chip 301 or 302, and these circuits may be at least partially connected to the connection pad.

Each connecting member 400 may be made of conductive material, for example, solder, and a material of the connecting member 400 is not particularly limited thereto. In addition, a connection method of the connecting member 400 is not limited thereto, and may include a land, a ball, a pin, or the like. In addition, the connecting member 400 may be formed as a multilayer or a single layer. The connecting member 400 may include a copper pillar and solder when formed as the multiple layers, may include solder including tin-silver or copper when formed as the single layer, and is not limited thereto.

Meanwhile, FIG. 3D shows that two semiconductor chips 301 and 302 are disposed on the printed circuit board, and the semiconductor chip is not limited thereto. In particular, the semiconductor chips 301 and 302 are shown as being connected die-to-die with the connection structure 200 while having the connection structure 200 therebetween, and are not necessarily limited thereto. The number and arrangement shape of the semiconductor chip 301 or 302, and the number, pitch, and arrangement shape of the connecting member 400 are not particularly limited, which may be modified sufficiently based on design details by those skilled in the art.

Meanwhile, among the contents other than the descriptions of the first semiconductor chip and the second semiconductor chip and the contents regarding the connecting member, the printed circuit board according to another exemplary embodiment may use the same configuration as that of the printed circuit board according to an exemplary embodiment, and the description thus omits redundant descriptions thereof.

### Manufacturing Method of Printed Circuit Board

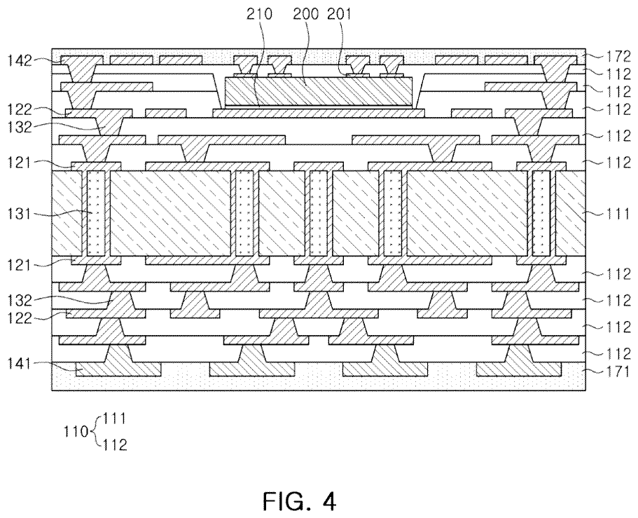

FIGS. 4 through 15 are cross-sectional views schematically illustrating the manufacturing method of a printed circuit board according to another exemplary embodiment.

The manufacturing method of a printed circuit board according to another exemplary embodiment may include: a process of forming the first pad 141 on the bottom of the insulating portion 110; a process of forming the second pad 142 on the top of the insulating portion 110; a process of forming the first solder resist layer 171 and the second solder resist layer 172 respectively on the bottom and top of the insulating portion 110; a process of forming the barrier layer 180 on each of the first pad 141 and the second pad 142; a process of forming the seed layer 190 on the barrier layer 180; a process of forming the first surface treatment layer 161 on the seed layer 190 disposed on the first pad 141; a process of forming the metal post 150 on the seed layer 190 disposed on the second pad 142; a process of forming the second surface treatment layer 162 on the metal post 150; and a process of removing a portion of each of the seed layer 190 and the barrier layer 180.

Referring to FIG. 4, a wiring part of the printed circuit board may be prepared. The wiring part may include the insulating portion 110 including the first insulating layer 111 and/or one or more second insulating layers 112, the first wiring layer 121 disposed on the first insulating layer 111, and the second wiring layer 122 disposed on or in the second insulating layer 112. The wiring part may include the first pad 141 disposed on the lowermost second insulating layer 112, and the second pad 142 disposed on the uppermost second insulating layer 112. A process of preparing the wiring part may include a process of forming the first wiring layer 121 on the first insulating layer 111, and a process of forming the second insulating layer 112 on the first insulating layer 111, and then forming the second wiring layer 122. The process of preparing the wiring part may include a process of forming each of the first pad 141 and the second pad 142 on the outermost second insulating layer 112. Here, a process of forming the insulating layer and the wiring layer may be performed through a known build-up process.

Meanwhile, the manufacturing method of a printed circuit board according to another exemplary embodiment may further include a process of forming the cavity that passes through at least a portion of the second insulating layer 112 to thus attach and mount the connection structure 200 using the adhesive layer 210, and bury the same in the second insulating layer 112, and is not necessarily limited thereto.

The method may include a process of forming the first solder resist layer 171 on the bottom of the wiring part, and may include a process of forming the second solder resist layer 172 on the top of the wiring part. The respective solder resist layers may be formed simultaneously, and are not necessarily limited thereto. A method of forming the first solder resist layer 171 or the second solder resist layer 172 may use any method of forming a known solder resist without limitation.

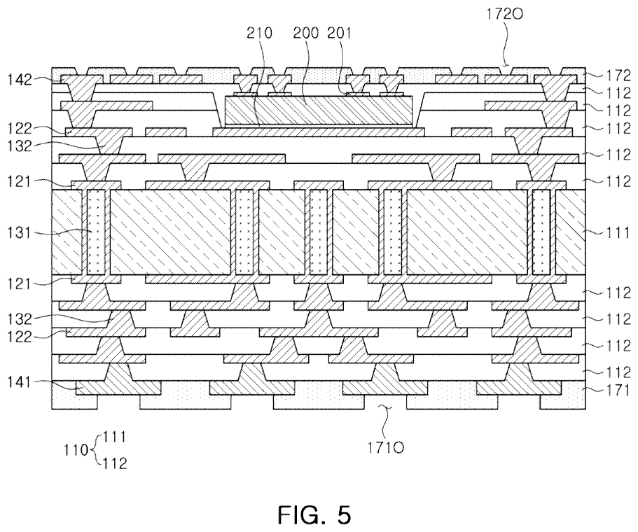

Next, referring to FIG. 5, the manufacturing method of a printed circuit board according to another exemplary embodiment may include a process of forming the first opening 171O in the first solder resist layer 171 and a process of forming the second opening 172O in the second solder resist layer 172. The first opening 171O may be formed on the first pad 141, and at least a portion of the first pad 141 may be exposed through the first opening 171O. The second opening 172O may be formed on the second pad 142, and at least a portion of the second pad 142 may be exposed through the second opening 172O. A method of forming the first opening 171O or the second opening 172O in the first solder resist layer 171 or the second solder resist layer 172 may use any known method of forming an opening without limitation.

Here, preprocessing may be performed to form the metal post 150. As the preprocessing, a desmear process may be performed to remove residues formed on the second solder resist layer 172, and the soft etching may be performed to process the exposed surface of the second pad 142.

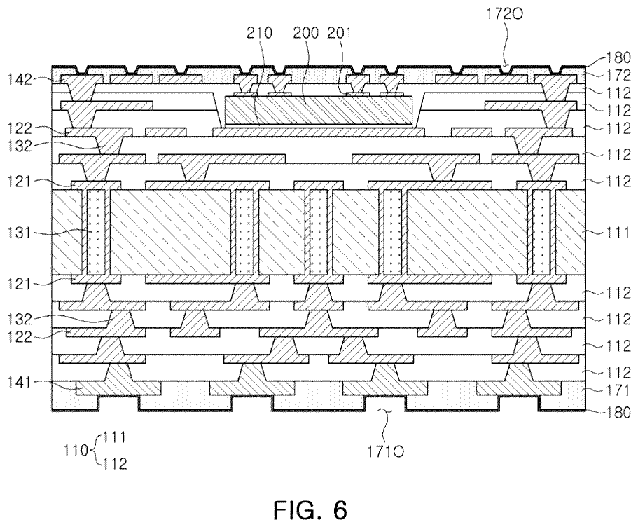

Next, referring to FIG. 6, the manufacturing method of a printed circuit board may include the process of forming the barrier layer 180. The barrier layer 180 may be formed on each of the first solder resist layer 171 and the second solder resist layer 172. The barrier layer 180 may have the thin film shape. Therefore, the barrier layer 180 may be disposed conformally based on the shape of the first solder resist layer 171 or the second solder resist layer 172. The barrier layer 180 may be disposed on the inner wall of the first opening 171O or the second opening 172O, and extend to the lower surface of the first solder resist layer 171 or the upper surface of the second solder resist layer 172.

A method of forming the barrier layer 180 may depend on a material of the barrier layer 180, the barrier layer 180 may be formed by the deposition. However, the method of forming the barrier layer 180 is not limited thereto, which is the same as described above in the description of the printed circuit board, and may use any method of forming a thin film without limitation.

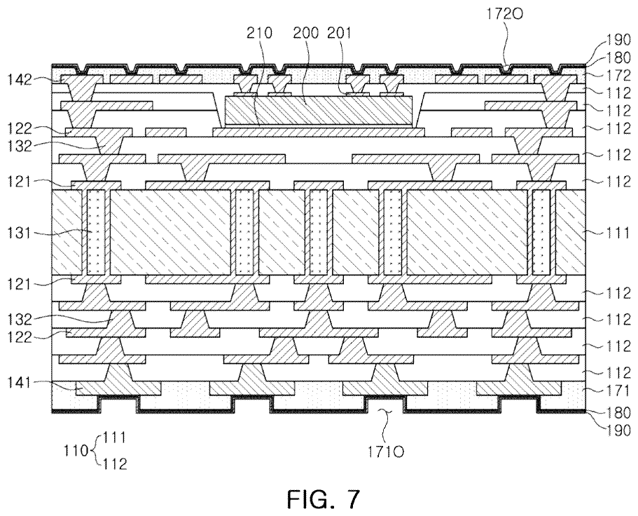

Next, referring to FIG. 7, the manufacturing method of a printed circuit board may include the process of forming the seed layer 190. The seed layer 190 may be formed on the barrier layer 180. The seed layer 190 may be formed on the barrier layer 180 disposed on the top of the second pad 142, and also be formed on the barrier layer 180 disposed on the bottom of the first pad 141. As the seed layer 190 is formed at the bottom of the first pad 141, the uniform plating may be formed by controlling the potential difference between the top and the bottom. The seed layer 190 may be formed by the electroless plating, formed by the chemical copper plating, is not limited thereto, and may also be formed by the sputtering. The seed layer 190 may be formed along the barrier layer 180, and formed conformally along the first solder resist layer 171 or the second solder resist layer 172.

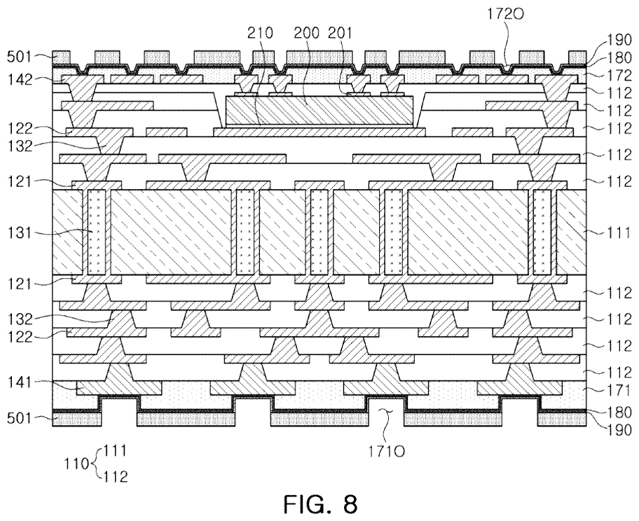

Next, referring to FIG. 8, the manufacturing method of a printed circuit board may include the process of forming a first resist 501. The first resist 501 may be a known plating resist. The first resist 501 may be disposed on the seed layer 190 and have an opening passing through a portion of the first resist 501 to thus open a region in which the plating is to be performed. The first resist 501 may be a resist to form the metal post 150, and may be a resist to form the first surface treatment layer 161. The lower first resist 501 may be formed on the seed layer 190 disposed on the first solder resist layer 171 to thus open a region in which the first surface treatment layer 161 is to be formed. The first resist 501 may be open to correspond to the first opening 171O of the first solder resist layer 171. The upper first resist 501 may be formed on the seed layer 190 disposed on the second solder resist layer 172 to thus open a region in which the metal post 150 is to be formed. That is, the upper first resist 501 may have an opening wider than the second opening 172O of the second solder resist layer 172.

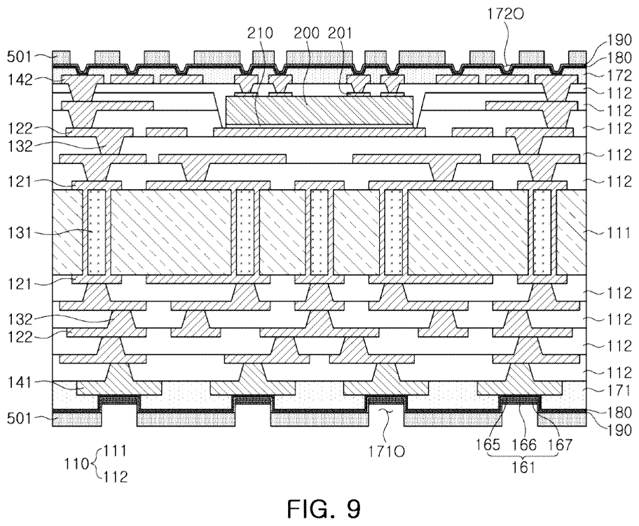

Next, referring to FIG. 9, the manufacturing method of a printed circuit board may include the process of forming the first surface treatment layer 161. The first surface treatment layer 161 may be formed on the first pad 141, and disposed on the barrier layer 180 and the seed layer 190, which are disposed on the first pad 141. As described above, the first surface treatment layer 161 may include the first metal layer 165, the second metal layer 166, and the third metal layer 167. The first surface treatment layer 161 may be formed in the first opening.

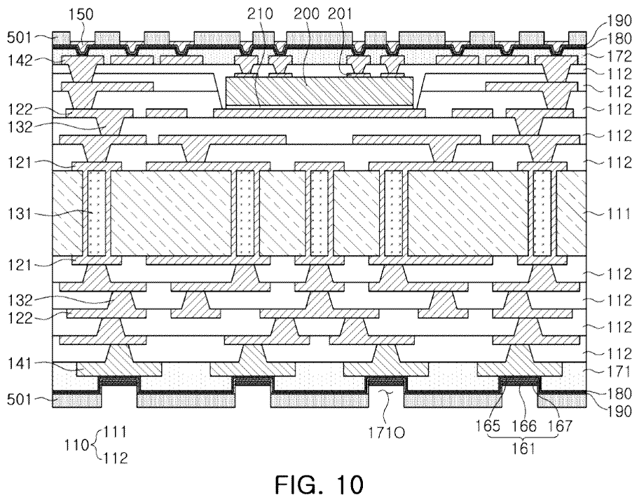

Next, referring to FIG. 10, the manufacturing method of a printed circuit board may include the process of forming the metal post 150. The metal post 150 may use the seed layer 190 as the plating seed, and may be formed through the electroplating using the first resist 501 as the plating resist. The process of forming the metal post 150 is not limited thereto, and may be performed using any method available to those skilled in the art.

Meanwhile, referring to FIGS. 4 through 10, it is shown that in the manufacturing method of a printed circuit board according to another exemplary embodiment, the top and bottom processing may be performed in the same process. However, the method is not necessarily limited thereto, and the bottom of the printed circuit board may first be processed to thus form the first surface treatment layer 161, and then the top of the printed circuit board may then be processed to perform the process of forming the metal post 150.

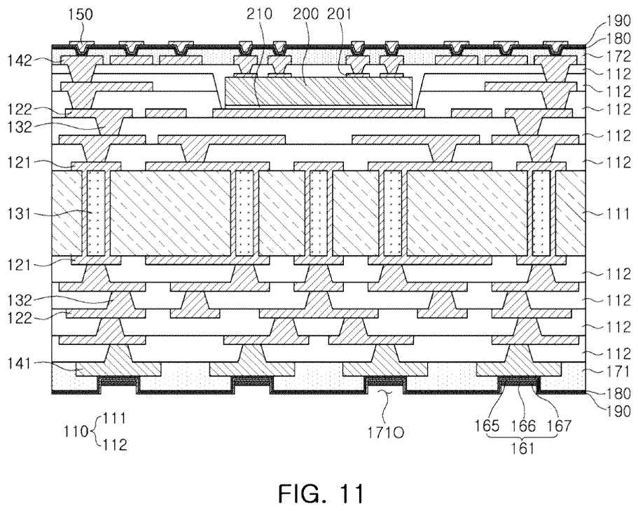

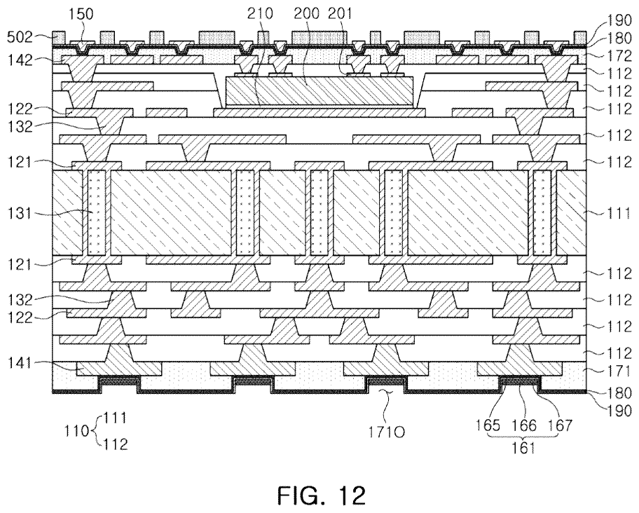

Next, referring to FIG. 11, the manufacturing method of a printed circuit board may include the process of removing the first resist 501. A method of removing the first resist 501 may be performed by a known method of removing the plating resist.

Next, referring to FIG. 12, the manufacturing method of a printed circuit board may include a process of forming a second resist 502. The second resist 502 may function as the plating resist, and include an opening where the second surface treatment layer 162 is to be formed. The second resist 502 may use the known resist, include the same material as the first resist 501, is not limited thereto, and select a material based on its plating type and material. The opening formed in the second resist 502 may be wider than the width of the metal post 150. As the opening is wider than the metal post 150, the second surface treatment layer 162 may cover the side surface of the metal post 150.

Meanwhile, in the printed circuit board according to an exemplary embodiment, the first resist 501 may be removed, and the process of forming the second resist 502 may then be performed separately rather than further processing the first resist 501 to have the opening wider than the metal post 150. That is, the opening may be formed by forming the second resist 502 separately and then performing an exposure and development process rather than expanding the opening by performing a mechanical/chemical processing on the cured first resist 501. That is, the process in the present disclosure is different from a case where the mechanical/chemical processing is performed targeting only a portion of the resist 501, thus preventing damage which may occur when a region adjacent to the opening of the first resist 501 is processed. That is, the seed layer 190 in the region in which the metal post 150 is formed and the seed layer 190 in the region exposed through the opening of the second resist 502 to form the second surface treatment layer 162 may have substantially the same feature as each other. Accordingly, the side surface of the metal post 150 may not be damaged, and the relationship between the upper and side surfaces of the metal post 150 may thus be the same.

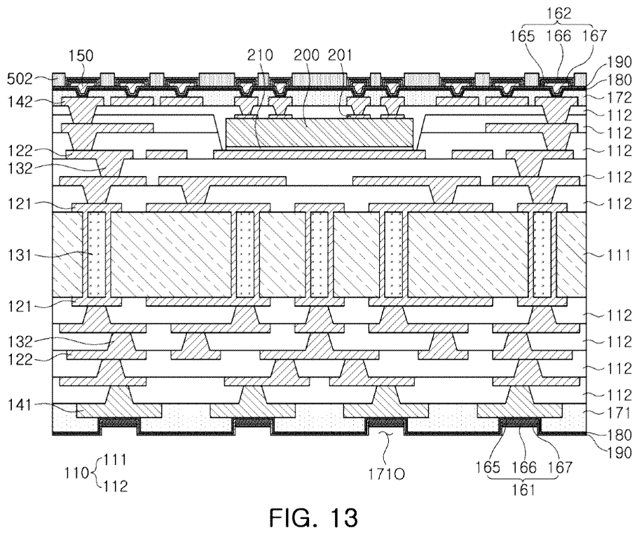

Next, referring to FIG. 13, the manufacturing method of a printed circuit board may include the process of forming the second surface treatment layer 162. The second surface treatment layer 162 may be formed in the opening region of the second resist 502, and cover the upper and side surfaces of the metal post 150. That is, the second surface treatment layer 162 may be formed on the metal post 150 exposed through the opening of the second resist 502. The second surface treatment layer 162 may include the first metal layer 165, the second metal layer 166, and the third metal layer 167. The content and method of forming the second surface treatment layer 162 overlap the contents regarding the first surface treatment layer 161, and are thus omitted.

As the second surface treatment layer 162 covers the side surface of the metal post 150, the metal post 150 may not be externally exposed in the process of removing portions of the seed layer 190 and the barrier layer 180. Therefore, the galvanic corrosion may not occur between the metal post 150 and the third metal layer 167. That is, the first metal layer 165 formed to be in contact with the metal post 150 may function as a barrier to prevent the exposure of the metal post 150.

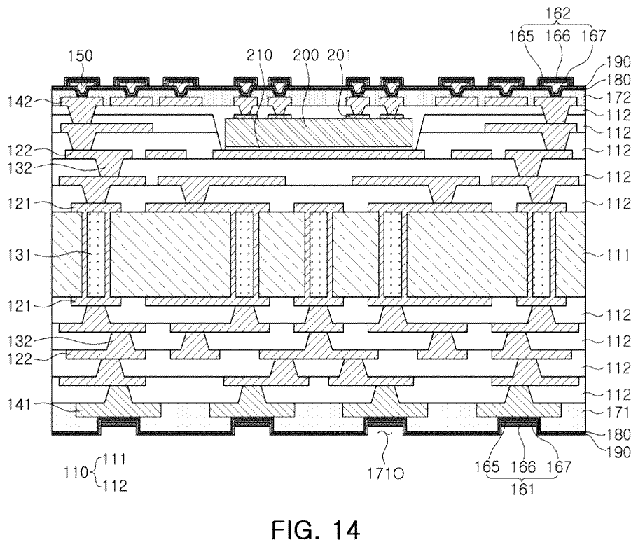

Next, referring to FIG. 14, the manufacturing method of a printed circuit board may include a process of removing the second resist 502. A method of removing the second resist 502 may be performed using a known resist removal method.

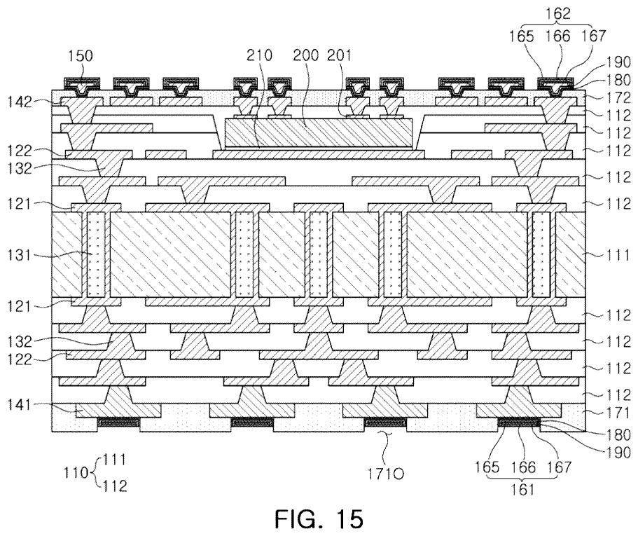

Next, referring to FIG. 15, the manufacturing method of a printed circuit board may include the process of removing a portion of the seed layer 190 and a portion of the barrier layer 180. The seed layer 190 and the barrier layer 180 may include different materials. Therefore, the process of removing a portion of the seed layer 190 may be performed, and the process of removing a portion of the barrier layer 180 may then be performed sequentially. However, the processes are not limited thereto, and may be performed simultaneously.

Even when the etchant or the like is used to remove a portion of the seed layer 190, the barrier layer 180 which includes a heterogeneous material may be disposed on the bottom of the seed layer 190, and the first metal layer 165 of the second surface treatment layer 162 may be disposed on the side surface of the metal post 150. Therefore, the galvanic corrosion may not occur in the metal post 150 and the second pad 142 in process of removing the seed layer 190.

The process of removing a portion of the barrier layer 180 may be performed to thus open a short-circuit state where the metal posts 150 are connected to each other, and allow the metal post 150 and the second pad 142 to perform their functions. Meanwhile, a portion of the seed layer 190 and a portion of the barrier layer 180 may be removed from the bottom of the printed circuit board, thus allowing the first pad 141 to perform its function.

As set forth above, the present disclosure may also provide the printed circuit board on which the pad and the metal post having the fine pitch may be mounted as the printed circuit board for mounting the electronic component, the semiconductor chip, or the like.

The present disclosure may also provide the printed circuit board which is prevented from the defect caused by the galvanic corrosion occurring in the lower pad and the surface treatment layer when forming the upper metal post.

The present disclosure may also provide the printed circuit board having the improved reliability.

In the present disclosure, the cross-sectional shape may be a cross-sectional shape of an object when the object is vertically cut or its cross-sectional shape when the object is viewed from the side. In addition, the planar shape may be a shape of an object when the object is horizontally cut, or its planar shape when the object is viewed from the top or bottom.

In the present disclosure, the top, the upper portion, the upper surface, or the like refer to the direction toward the surface where the electronic component may be mounted based on the cross section of the drawings for convenience, and the bottom, the lower portion, the lower surface, or the like refer to the opposite direction. However, these directions are defined for convenience of explanation, and the scope of the claims is not particularly limited by the directions defined as described above.

In the present disclosure, the connection between two components conceptually includes their indirect connection through an adhesive layer or the like as well as their direct connection. In addition, the expression, “electrically connected,” conceptually includes a physical connection and a physical disconnection. In addition, the term such as “first” or “second,” is used only to distinguish a component from another component, and may not limit the sequence or importance of the component. In some cases, a first component may be referred to as a second component without departing from the scope of the claims set forth herein. Similarly, a second component may also be referred to as a first component.

In the present disclosure, the expression, “substantially,” may be determined by including a process error, a positional deviation, an error in measurement, and the like that occur in the manufacturing process. For example, being “substantially” vertical may include not only the case of being completely vertical, but also the case of being approximately vertical. In addition, being “substantially” coplanar may include not only the case of being completely on the same plane, but also the case of being approximately on the same plane. For example, elements that are substantially coplanar may lie in planes that differ from each other by 1° or less.

In the present disclosure, the same material may include the materials of the same type as well as exactly the same material. Therefore, and a specific composition ratio of the material may be slightly different from each other although their compositions are substantially the same as each other.

The expression, “an exemplary embodiment,” used herein does not refer to the same exemplary embodiment, and is provided to emphasize each particular feature different from that of another exemplary embodiment. However, the exemplary embodiments provided herein do not exclude being implemented in conjunction with the features of another exemplary embodiment. For example, one element described in a particular exemplary embodiment may be understood as a description related to another exemplary embodiment even if the element is not described in another exemplary embodiment, unless an opposite or contradictory description is provided therein.

The terms used herein are used only to describe an exemplary embodiment rather than limit the present disclosure. Here, a term of a singular number includes its plural number unless explicitly interpreted otherwise in context.

While the example embodiments have been shown and described above, it will be apparent to those skilled in the art that modifications and variations could be made without departing from the scope of the present disclosure as defined by the appended claims.

What is claimed is:

1. A printed circuit board comprising:
an insulating portion;
a first pad disposed on a bottom of the insulating portion;
a first solder resist layer disposed on the bottom of the insulating portion, covering at least a first portion of the first pad, and having a first opening overlapping at least a second portion of the first pad;
a first barrier layer disposed on the second portion of the first pad corresponding to the first opening;
a first surface treatment layer disposed on the first barrier layer;
a second pad disposed on a top of the insulating portion;
a second solder resist layer disposed on the top of the insulating portion, covering at least a third portion of the second pad, and having a second opening overlapping at least a fourth portion of the second pad;
a metal post disposed on the second pad, and having at least a portion disposed in the second opening; and
a second barrier layer disposed between the second pad and the metal post.

2. The printed circuit board of claim 1, wherein the first barrier layer extends to a portion of an inner wall of the first opening.

3. The printed circuit board of claim 1, wherein the first barrier layer is disposed along at least a portion of a side surface of the first surface treatment layer.

4. The printed circuit board of claim 1, wherein the first surface treatment layer includes a first metal layer disposed on the barrier layer, a second metal layer disposed on the first metal layer, and a third metal layer disposed on the second metal layer.

5. The printed circuit board of claim 1, further comprising a first seed layer disposed between the first barrier layer and the surface treatment layer.

6. The printed circuit board of claim 5, wherein the first barrier layer extends to a portion of an inner wall of the first opening, and
the first seed layer extends along the first barrier layer.

7. The printed circuit board of claim 6, wherein the first barrier layer, the first seed layer, and the first surface treatment layer have substantially coplanar surfaces, respectively.

8. The printed circuit board of claim 1, wherein one surface of the first surface treatment layer is a step from a lower surface of the first solder resist layer.

9. The printed circuit board of claim 1, wherein the barrier layer includes a metal different from a metal of the first pad.

10. The printed circuit board of claim 1, wherein the second barrier layer is disposed on the second pad, and extends to portions of an inner wall of the second opening and an upper surface of the second solder resist.

11. The printed circuit board of claim 10, further comprising a second seed layer disposed between the second barrier layer and the metal post, and extending along the second barrier layer.

12. The printed circuit board of claim 11, further comprising a second surface treatment layer disposed on the metal post.

13. The printed circuit board of claim 12, wherein the second surface treatment layer, the second barrier layer, and the second seed layer have substantially coplanar surfaces, respectively.

14. The printed circuit board of claim 12, wherein the second surface treatment layer includes a first metal layer disposed on the metal post, a second metal layer disposed on the first metal layer, and a third metal layer disposed on the second metal layer.

15. The printed circuit board of claim 1, wherein the insulating portion includes a first insulating layer and a second insulating layer, and the printed circuit board further comprises a first wiring layer and a second wiring layer disposed on the first insulating layer and the second insulating layer, respectively, wherein the first wiring layer and the second wiring layer are connected to the first pad and the second pad.

16. A printed circuit board comprising:
an insulating portion;
a pad disposed on a top of the insulating portion;
a solder resist layer disposed on the top of the insulating portion, covering at least a first portion of the pad, and having an opening overlapping at least a second portion of the pad;
a barrier layer in contact with the pad, and extending onto portions of an inner wall of the opening and an upper surface of the solder resist; and
a metal post disposed on the barrier layer,
wherein:
the pad includes a first metal, and
the barrier layer includes a material different from the first metal of the pad.

17. The printed circuit board of claim 16, wherein the barrier layer is free of the first metal.

18. The printed circuit board of claim 17, wherein the material of the barrier layer includes at least one selected from titanium (Ti), aluminum (Al), tin (Sn), and lead (Pb).

19. The printed circuit board of claim 17, wherein the material of the barrier layer 180 includes a conductive carbon-based material.
